(19) United States
(12) Patent Application Publication
(10) Pub. No.: US 2024/0224451 A1
(43) Pub. Date: Jul. 4, 2024

(54) BATTERY CHARGER HANDLE

(71) Applicant: Enatel, Christchurch (NZ)

(72) Inventors: Chuan Cheong Yew, Christchurch (NZ); Ryan Cameron Taylor, Christchurch (NZ)

(21) Appl. No.: 18/554,699

(22) PCT Filed: Oct. 19, 2021
(86) PCT No.: PCT/NZ2021/050178

§ 371 Date: Oct. 10, 2023

Related U.S. Application Data
(60) Provisional application No. 63/182,461, filed on Apr. 30, 2021.

(51) Int. Cl. H05K 5/02; H02J 7/00

(52) U.S. Cl. CPC H05K 5/023; H02J 7/0042; H05K 5/0213

(57) ABSTRACT

A handle for a battery charger includes a first coupling portion, the first coupling portion comprising a contact portion configured to be coupled to the battery charger, and a cover portion, the cover portion having a first width, wherein a depth from the contact portion to the cover portion is 45 mm or more so as to enforce a minimum spacing between adjacent battery chargers in a multi-charger system to permit airflow. The 5 handle further includes a second coupling portion configured to be coupled to the battery charger body. the second coupling portion having a second width, and a grip portion disposed between the first coupling portion and the second coupling portion, the grip portion having a third width that is less than the first width and the second width. The cover portion may substantially cover a vent on the battery charger to prevent debris from 0 entering the vent.

### CROSS-REFERENCE TO RELATED APPLICATION

This application claims priority to U.S. provisional application No. 63/182,461, filed Apr. 30, 2021, which application is hereby incorporated by reference in its entirety.

### TECHNICAL FIELD

This disclosure generally relates to a battery charger body, including a handle for the battery charger body.

### BACKGROUND

Known battery charger bodies, particularly chargers for industrial applications, generally do not include handles, and further do not include handles that permit airflow into and out of air flow ports of the charger while preventing entry of foreign objects into the airflow ports.

### SUMMARY

In a first aspect of the present disclosure, a handle for a battery charger body is provided. The handle includes a first coupling portion, the first coupling portion including a contact portion configured to be coupled to the battery charger body and a cover portion, the cover portion having a first width, wherein a depth from the contact portion to the cover portion is 45 mm or more. The handle further includes a second coupling portion configured to be coupled to the battery charger body, the second coupling portion having a second width, and a grip portion disposed between the first coupling portion and the second coupling portion, the grip portion having a third width that is less than the first width and the second width.

In an embodiment of the first aspect, the first coupling portion further includes an extension portion disposed between the contact portion and the cover portion, the extension portion having a depth of 45 mm or more. In a further embodiment of the first aspect, the contact portion includes a planar portion configured to abut the battery charger body, wherein the extension portion is substantially perpendicular to the plane of the planar portion.

In an embodiment of the first aspect, the first width is larger than the second width.

In an embodiment of the first aspect, the grip portion includes a plurality of transverse channels along the width of the grip portion.

In an embodiment of the first aspect, the cover portion includes an uninterrupted, continuous surface having the first width and configured to prevent the passage of debris.

In an embodiment of the first aspect, the depth from the contact portion to the cover portion is 60 mm or more.

In a second aspect of the present disclosure, a battery charger is provided. The battery charger includes a housing defining a vent and a handle, the handle including a coupling portion coupled to the housing, the coupling portion comprising a cover portion, the cover portion disposed over the vent, and a grip portion adjacent to the coupling portion and the second coupling portion, the grip portion having a width that is less than a width of the first coupling portion.

In an embodiment of the second aspect, the coupling portion is a first coupling portion, the handle further including a second coupling portion coupled to the housing, and the grip portion is disposed between the first coupling portion and the second coupling portion. In a further embodiment of the second aspect, the first coupling portion has a first width, the second coupling portion has a second width, and the grip portion has a third width, wherein the third width is less than the first width and the second width. In a further embodiment of the second aspect, the first width is larger than the second width.

In an embodiment of the second aspect, an outermost portion of the handle has a depth of at least 45 mm from the housing. In a further embodiment of the second aspect, the grip portion has a depth from the housing of at least 45 mm. In a further embodiment of the second aspect, an outermost portion of the handle has a depth of at least 60 mm from the housing.

In an embodiment of the second aspect, the grip portion includes a plurality of transverse channels along the width of the grip portion.

In an embodiment of the second aspect, the cover portion includes an uninterrupted, continuous surface having the width of the first coupling portion and configured to prevent the passage of debris.

In an embodiment of the second aspect, the first and second coupling portions are coupled to a substantially planar surface of the housing, wherein the depth is measured from the planar surface of the housing.

In a third aspect of the present disclosure, a battery charger is provided. The charger includes a housing defining a vent having a width and a length and a handle. The handle includes a coupling portion coupled to the housing, the coupling portion including an uninterrupted, continuous cover portion that covers an entire area of a transverse projection of the width and length of the vent, and a grip portion adjacent to the coupling portion, the grip portion having a width that is less than a width of the coupling portion.

In an embodiment of the third aspect, the coupling portion is a first coupling portion, and the handle further includes a second coupling portion coupled to the housing, wherein the grip portion is disposed between the first coupling portion and the second coupling portion.

In an embodiment of the third aspect, an outermost portion of the handle is at least 45 mm from the housing.

### BRIEF DESCRIPTION OF THE DRAWINGS

FIG. 1 is a front view of an example battery charger.

FIG. 2 is a perspective view of the battery charger of FIG. 1.

FIG. 3 is a side view of the battery charger of FIG. 1.

FIG. 4 is a perspective view of an example handle for the battery charger of FIG. 1.

FIG. 5 is a rear view of the handle of FIG. 4.

FIG. 6 is an end view of the handle of FIG. 4.

FIG. 7 is an enlarged side view of a grip portion of the handle of FIG. 4.

FIG. 8 is a side view of the handle of FIG. 4.

FIG. 9 is a top view of the handle of FIG. 4.

FIG. 10 a front view an example battery charger.

FIG. 11 is a perspective view of the battery charger of FIG. 10.

FIG. 12 is a side view of the battery charger of FIG. 10.

FIG. 13 is a perspective view of an example handle for the battery charger of FIG. 10.

FIG. 14 is a rear view of the handle of FIG. 13.

FIG. 15 is a side view of the handle of FIG. 13.

FIG. 16 is a top view of the handle of FIG. 13.

### DETAILED DESCRIPTION

A battery charging system may include one or more battery chargers, each configured to be carried and transported by an individual. Each battery charger may be configured to charge small electric vehicle batteries. For example, the one or more chargers may be deployed at a site for charging a fleet of electric vehicles that are used at the site or that are based at the site. Accordingly, a battery charger housing with a handle that enables proper spacing for airflow between adjacent mounted chargers, that prevents solid and liquid debris from entering or blocking airflow ports on the charger, and that enables comfortable carrying by a user may improve over known battery chargers.

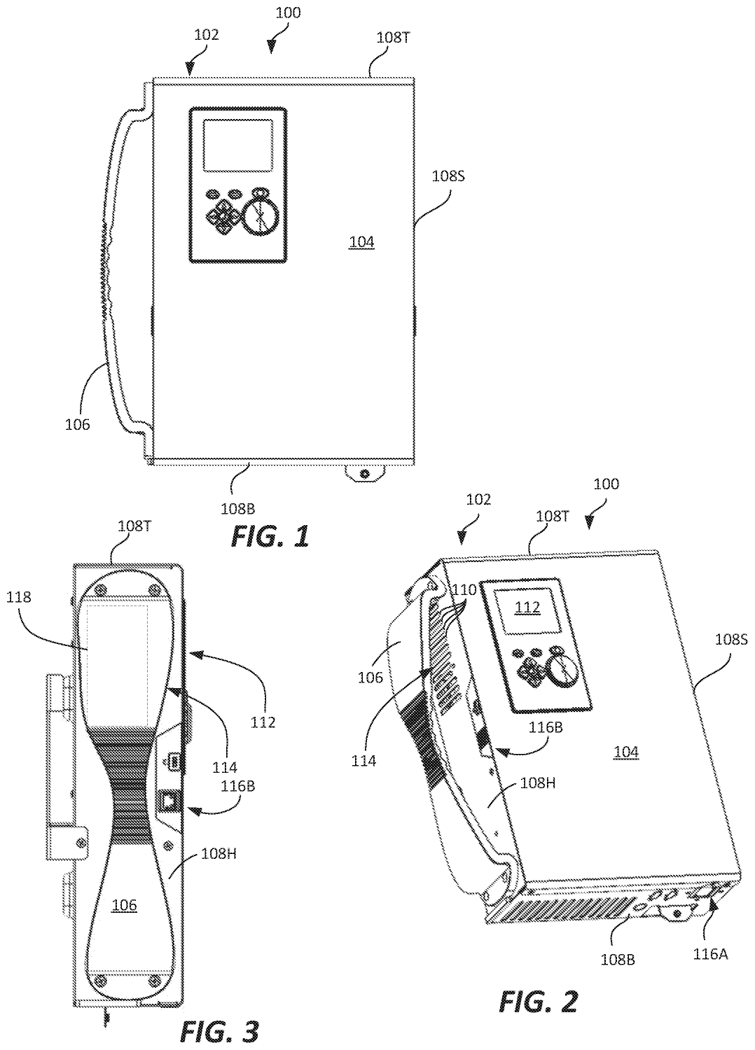

FIGS. 1, 2, and 3 are front, perspective, and side views, respectively, of an example battery charger 100. The charger 100 may include a body 102 that includes a main housing portion 104 and a handle 106. The main housing portion 104 may include one or more walls 108, such as a top wall 108T, bottom wall 108B, and one or more sidewalls 108S, for example. The walls 108 of the charger main housing portion 104 may define a rectangular or other prism, with each wall separated from adjacent walls by respective edges. The walls 108 of the housing may define an interior in which the electronic portions of the charger 100 are disposed. One or more of the walls 108 of the housing 104 may define one or more airflow apertures 110 (some, but not all, of which are indicated in FIG. 2) arranged to permit air flow into and out of the interior, whereby heat generated by the charger electronics may be expelled from the housing. In some embodiments, the one or more airflow apertures 110 on a given wall 108 may form a vent 114. The vent 114 may provide an air intake and/or exhaust.

The handle 106 may be disposed over a wall 108 that defines a vent 114, and more specifically at least a portion of the handle 106 may be disposed over at least a portion of the vent 114. For example, the handle 106 may be disposed laterally outward from the wall 108, such that a line perpendicular to the wall passes through the handle. A wall 108 over which the handle is disposed may be referred to herein as a “handle-side wall” 108H. The handle 106 have cover an entire transverse projection 118 (shown in dashed lines in FIG. 3) of the length and width of the vent 114, in some embodiments.

In some embodiments, a handle-side wall 108H may be adjacent to (e.g., may share an edge with) a wall 108 on which a display 112 or other output or user input device is disposed. In some embodiments, a handle-side wall 108H may be adjacent to a wall 108 that includes one or more power or data ports 116A. In some embodiments, data or other ports 116B may be provided on the handle-side wall 108H. The handle 106 may prevent cables connected to such ports 116B from becoming bent or crimped by another battery charger or other object being placed too close to the charger 100 when the cables are connected to the charger 100.

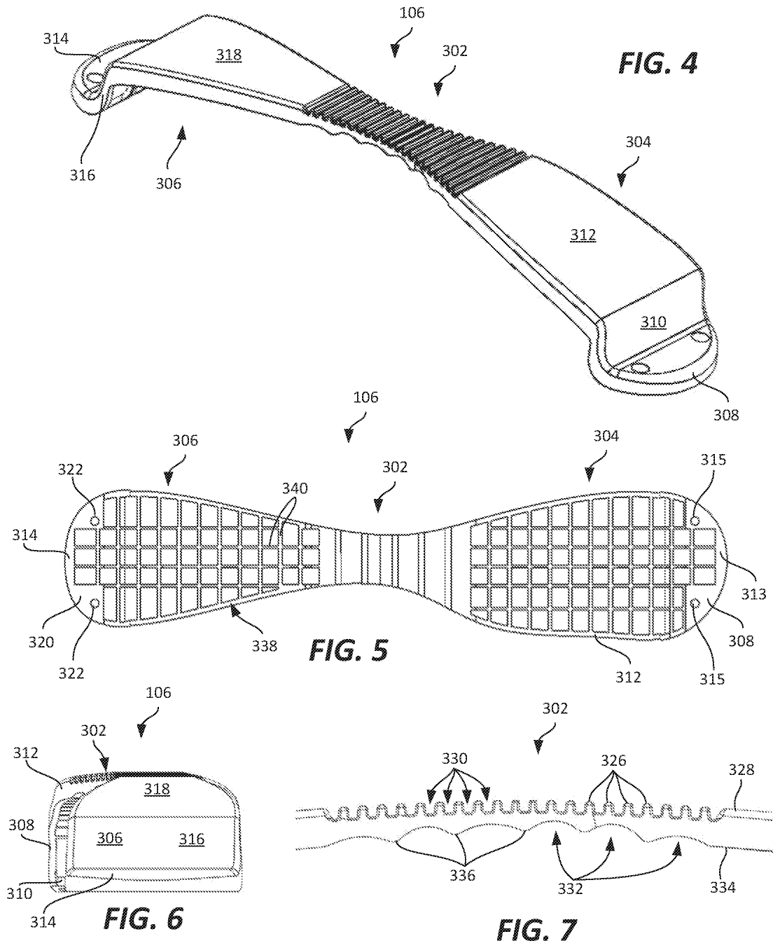

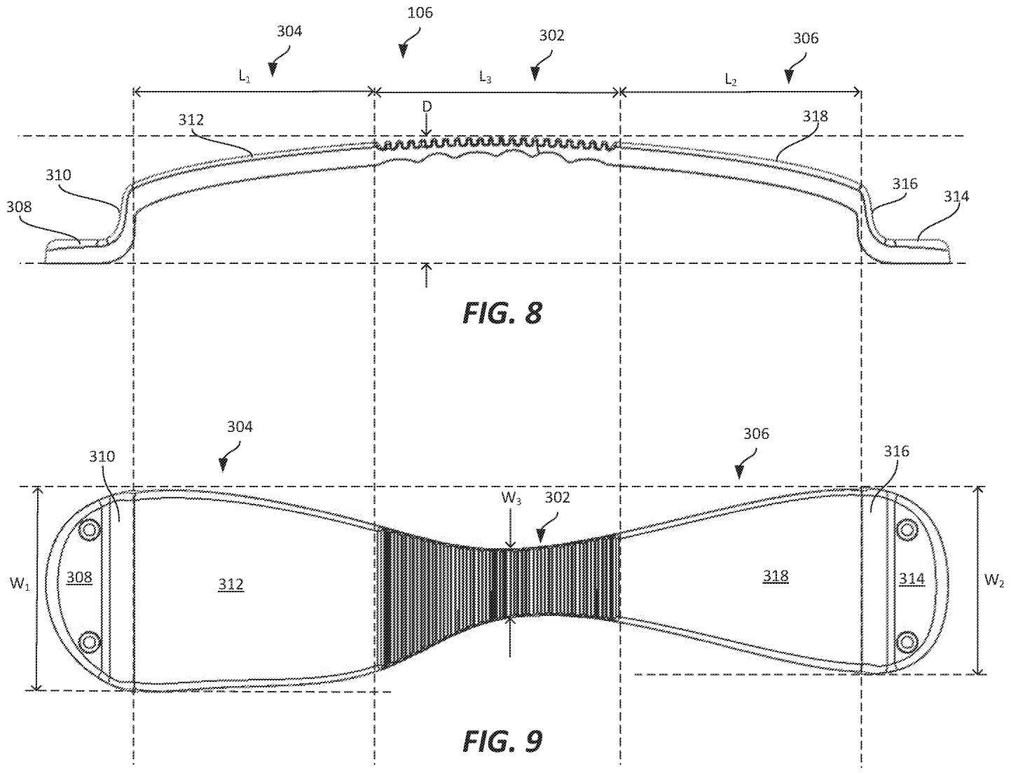

FIGS. 4-9 are various views of the handle 106. The handle 106 may include a grip portion 302 disposed between a first coupling portion 304 and a second coupling portion 306. The first and second coupling portions 304, 306 may be configured to be coupled to the handle-side wall 108H. The first coupling portion 304 may be disposed over the vent 114 and may be sized and shaped to cover the entire projected area of the vent so as to prevent debris from entering the vent 114, in some embodiments.

The first coupling portion 304 may include a contact portion 308, an extension portion 310, and a cover portion 312. The contact portion 308 may include a substantially planar lower surface 313 configured to abut a wall (e.g., the handle-side wall 108H) of the battery housing 104 and one or more apertures 315 through which one or more fasteners may be inserted to affix the contact portion 308 to the housing 104. The extension portion 310 may extend in a direction that is substantially perpendicular to the plane of the planar lower surface 313 of the contact portion 308, in some embodiments. The extension portion 310 may extend from the contact portion 308 to the cover portion 312. The cover portion 312 may have a length L₁ extending from the extension portion 310 to the grip portion 302 and a width W₁ that is perpendicular to the length L₁. The length L₁ and width W₁ of the cover portion 312 may define an area that covers a transverse projection of a vent 114 over which the cover portion 312 is disposed, in some embodiments. The cover portion 312 may have an uninterrupted, continuous surface configured to prevent the passage of debris through the cover portion 312, in some embodiments, so as to prevent such debris from entering a vent 114 of the battery charger 100.

The second coupling portion 306 may include a contact portion 314, an extension portion 316, and a main portion 318. The contact portion 314 may include a substantially planar lower surface 320 configured to abut a wall of the battery housing and one or more apertures 322 through which one or more fasteners may be inserted to affix the contact portion 314 to the housing. The extension portion 316 may extend in a direction that is substantially perpendicular to the planar lower surface 320 of the contact portion 314, in some embodiments. The extension portion 316 may extend from the contact portion 314 to the main portion 318. The main portion 318 may have a length L₂ extending from the extension portion 316 to the grip portion 302 and a width W₂ that is perpendicular to the length L₂. The length L₂ and width W₂ of the main portion 318 may define an area that is smaller than the area of the cover portion 312 of the first coupling portion 304, in some embodiments. For example, the width W₁ of the cover portion 312 of the first coupling portion 304 may be larger than the width W₂ of the main portion 318 of the second coupling portion 306, in some embodiments.

One or both of the first coupling section 304 and the second coupling section 306 may have a waffle substructure 338 (best shown in FIG. 5), in some embodiments. The waffle substructure 338 may be provided on an underside of the first coupling section 304 and/or the second coupling section 306 and may include a plurality of connecting struts 340 along the width and length of the underside.

The grip portion 302 of the handle 106 may include a plurality of generally rectangular transverse protrusions or ridges 326 (some, but not all, of which are indicated in FIG. 6) on an outer surface 328, with the ridges 326 separated by generally rectangular transverse recesses or channels 330 (some, but not all, of which are indicated in FIG. 7) defined in the outer surface 328. The grip portion 302 may further include a plurality of generally rounded recesses 332 (some, but not all, of which are indicated in FIG. 7) defined in an inner surface 334 of the grip portion 302, separated by generally rounded transverse protrusions 336 (some, but not all, of which are indicated in FIG. 7). The rounded recesses 332 may act as finger holds, in some embodiments, for a user's fingers. The transverse protrusions 326 and recesses 330 may enable the grip portion 302 to flex and support the weight of an attached battery charger when carried by a user.

The grip portion 302 may define a maximum distance D of an outermost portion of the handle 106 from the handle-side wall 106H (which distance may be referred to herein as a depth D of the handle 106). The maximum distance D may act as a de facto minimum spacing between the handle-side wall 106H and any adjacent objects, including other chargers mounted next to the charger 100, or a distance from the charger 100 to a surface if the charger 100 is mounted or placed with the handle-side wall 108H facing the surface. In some embodiments, the handle 106 (e.g., the grip portion 302) may define a depth D of 45 millimeters (mm) or more. In some embodiments, the handle 106 (e.g., the grip portion 302) may define a depth D of 60 millimeters (mm) or more. In some embodiments, the cover portion 312 may define a depth D of 45 millimeters (mm) or more, whether or not that is the maximum depth of the handle. In some embodiments in which the handle 106 includes one or more contact portion planar surfaces 313, 320 configured to abut the battery charger housing, the depth D of the handle 106 may be measured from the plane of the planar surface 313, 320.

One or both of the cover portion 312 and the main portion 318 may be arcuate and may increase in depth from the respective extension portions 310, 316 to the grip portion 302, in some embodiments. Similarly, the grip portion 302 may be arcuate and may increase in depth from the first and second coupling portions 304, 306 to the center of the grip portion 302, in some embodiments. Accordingly, in some embodiments, the center of the grip portion 302 may define the maximum depth of the handle 106. In other embodiments, the cover portion 312, main portion 318, and grip portion 302 may define a single, substantially consistent depth. In such embodiments, any of the cover portion 312, main portion 318, or grip portion 302 may be considered to define the maximum depth of the handle 106.

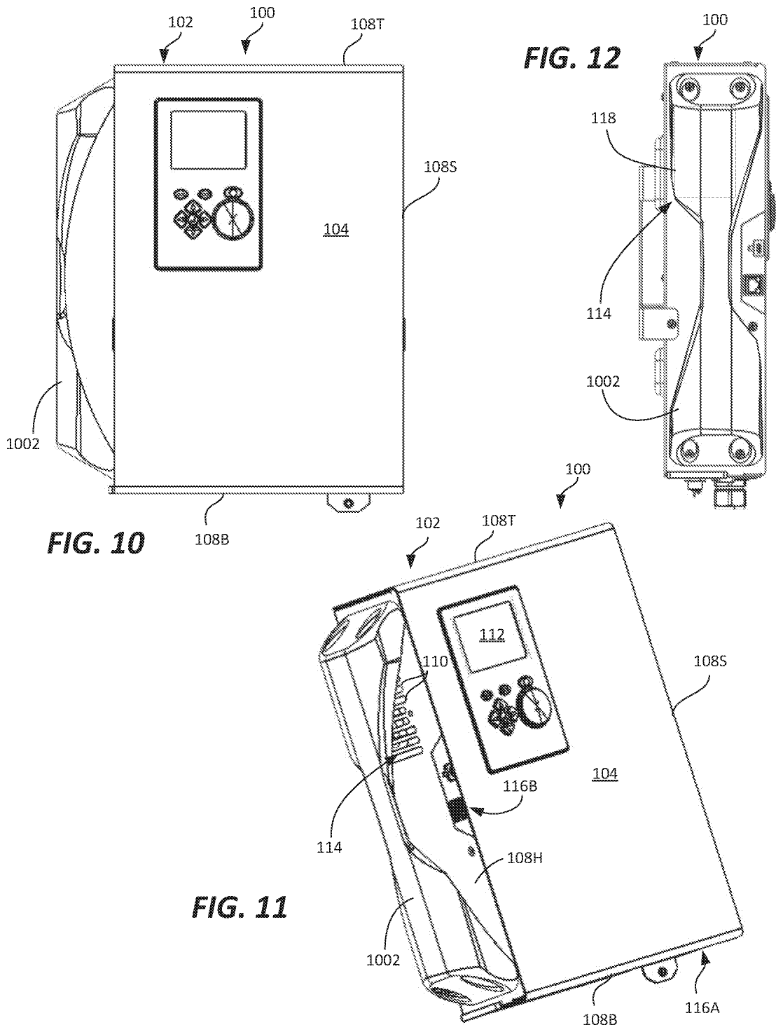

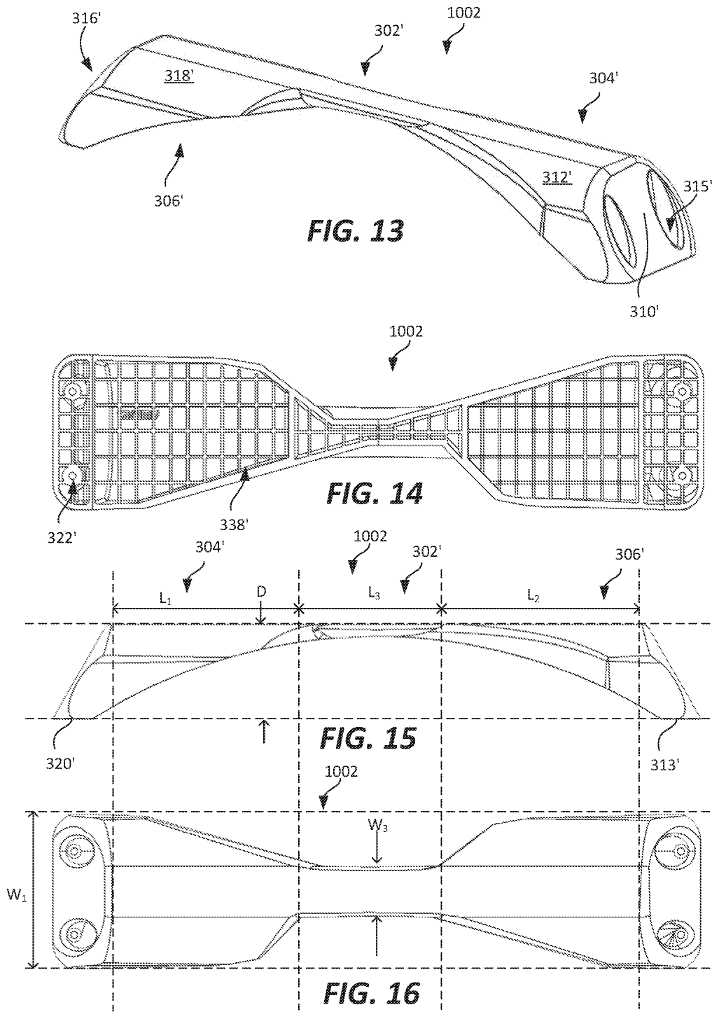

FIGS. 10, 11, and 12 illustrate a second embodiment of a handle 1002 disposed on the charger 100, and FIGS. 13-16 illustrate the handle 1002. The handle 1002 includes many similar features to the handle 106. Features of the handle 1002 labeled in FIGS. 13-16 with numerals in prime (′) notation have functionally similar features to the corresponding features of the handle 106 except as described differently herein.

Referring to FIG. 12, the handle 1002 may be disposed over a wall 108H that defines a vent 114, and more specifically at least a portion of the handle 1002 may be disposed over at least a portion of the vent 114. For example, the handle 1002 may be disposed laterally outward from the wall 108H, such that a line perpendicular to the wall 108H passes through the handle 1002. The handle 1002 may cover an entire transverse projection 118 of the length and width of the vent 114, in some embodiments.

The first coupling portion 304′ may be disposed over the vent 114 and may be sized and shaped to cover a significant portion (e.g., 80% or more, or 90% or more) of the transverse projection 118 of the vent 114, in some embodiments, so as to prevent debris from entering the vent 114.

The extension portion 310′ may extend from a planar portion 313′ to the cover portion 312′. The length L₁ and width W₁ of the cover portion 312′ may define an area that covers a significant portion of the transverse projection of the vent 114 over which the cover portion 312′ is disposed, in some embodiments. The cover portion 312′ may have an uninterrupted, continuous surface configured to prevent the passage of debris through the cover portion 312′. In the embodiment illustrated, the continuous surface of the cover portion 312′ includes an upper portion that is substantially parallel with the plane of the planar portion 313′ and two lateral angled portions, each of which extends downward from the upper portion.

The main portion 318′ of the second coupling portion 306′ may have the same width W₁ as the first coupling portion 304′, in some embodiments. The length L₂ and width W₁ of the main portion 318′ may define an area that is substantially the same as the area of the cover portion 312′ of the first coupling portion 304′, in some embodiments.

The waffle substructure 338′ of the handle 1002 may be provided on the entire underside of the handle 1002, in some embodiments, including the first and second coupling portions 304′, 306′, and the grip portion 302′.

The grip portion 302′, first coupling portion 304′, and second coupling portion 306′ may define a substantially planar upper surface that defines the depth D of the handle 1002, in some embodiments. As described with respect to handle 106, the depth D may be 45 mm or more, or 60 mm or more, in embodiments. Respective lower surfaces of the first coupling portion 304′ and second coupling portion 306′ may be arcuate and may increase in depth from the extension portions 310′, 316′ to the grip portion 302′.

In some embodiments, features from the handle 106 may be provided on the handle 1002, and vice-versa. For example, ridges 326 and channels 330, and/or recesses 332 and protrusions 336 may be provided in the grip portion 302′, in embodiments. In another example, the first and second coupling portions 304, 306 may be provided with an upper portion that is substantially parallel with the plane of the planar portion 313 and two lateral angled portions, each of which extends downward from the upper portion, as illustrated and described with respect to handle 1002.

The handles 106, 1002 of the instant disclosure may offer many benefits. The handles 106, 1002 be used to pick up and carry the charger 100, and may provide further capabilities that protect the charger 100 to ensure its ongoing operation. These capabilities include: (1) the handles 106, 1002 may be positioned over the airflow point 114 to ensure a minimum spacing of unrestricted space to adjacent chargers 100 or walls so that the airflow to the charger is never blocked; (2) the handles 106, 1002 may reduce the chances of foreign objects from falling into an airflow point 110 while still permitting airflow. The handles 106, 1002 may be particularly effective at prevent foreign objects from entering or blocking an airflow port or vent 114 when the charger 100 is stored or positioned with the port or vent 114 upwards.

In some embodiments, the handles 106, 1002 may further include storage compartments within the handle 106, 1002 for cables or connectors. The handles 106, 1002 may be varied in style and aesthetic design.

While this disclosure has described certain embodiments, it will be understood that the claims are not intended to be limited to these embodiments except as explicitly recited in the claims. On the contrary, the instant disclosure is intended to cover alternatives, modifications and equivalents, which may be included within the spirit and scope of the disclosure. Furthermore, in the detailed description of the present disclosure, numerous specific details are set forth in order to provide a thorough understanding of the disclosed embodiments. However, it will be obvious to one of ordinary skill in the art that systems and methods consistent with this disclosure may be practiced without these specific details. In other instances, well known methods, procedures, components, and circuits have not been described in detail as not to unnecessarily obscure various aspects of the present disclosure.

1. A handle for a battery charger body, the handle comprising:
a first coupling portion, the first coupling portion comprising a contact portion configured to be coupled to the battery charger body and a cover portion, the cover portion having a first width, wherein a depth from the contact portion to the cover portion is 45 mm or more;
a second coupling portion configured to be coupled to the battery charger body, the second coupling portion having a second width;
a grip portion disposed between the first coupling portion and the second coupling portion, the grip portion having a third width that is less than the first width and the second width.

2. The handle of claim 1, wherein the first coupling portion further comprises an extension portion disposed between the contact portion and the cover portion, the extension portion having a depth of 45 mm or more.

3. The handle of claim 2, wherein the contact portion comprises a planar portion configured to abut the battery charger body, wherein the extension portion is substantially perpendicular to the plane of the planar portion.

4. The handle of claim 1, wherein the first width is larger than the second width.

5. The handle of claim 1, wherein the grip portion comprises a plurality of transverse channels along the width of the grip portion.

6. The handle of claim 1, wherein the cover portion comprises an uninterrupted, continuous surface having the first width and configured to prevent the passage of debris.

7. The handle of claim 1, wherein the depth from the contact portion to the cover portion is 60 mm or more.

8. A battery charger, comprising:
a housing defining a vent; and
a handle comprising:
a coupling portion coupled to the housing, the coupling portion comprising a cover portion, the cover portion disposed over the vent; and
a grip portion adjacent to the coupling portion and the second coupling portion, the grip portion having a width that is less than a width of the first coupling portion.

9. The battery charger of claim 8, wherein the coupling portion is a first coupling portion, the handle further comprising:
a second coupling portion coupled to the housing;
wherein the grip portion is disposed between the first coupling portion and the second coupling portion.

10. The battery charger of claim 9, wherein the first coupling portion has a first width, the second coupling portion has a second width, and the grip portion has a third width, wherein the third width is less than the first width and the second width.

11. The battery charger of claim 10, wherein the first width is larger than the second width.

12. The battery charger of claim 8, wherein an outermost portion of the handle has a depth of at least 45 mm from the housing.

13. The battery charger of claim 12, wherein the grip portion has a depth from the housing of at least 45 mm.

14. The battery charger of claim 12, wherein an outermost portion of the handle has a depth of at least 60 mm from the housing.

15. The battery charger of claim 8, wherein the grip portion comprises a plurality of transverse channels along the width of the grip portion.

16. The battery charger of claim 8, wherein the cover portion comprises an uninterrupted, continuous surface having the width of the first coupling portion and configured to prevent the passage of debris.

17. The battery charger of claim 8, wherein the first and second coupling portions are coupled to a substantially planar surface of the housing, wherein the depth is measured from the planar surface of the housing.

18. A battery charger, comprising:
a housing defining a vent having a width and a length; and
a handle comprising:
a coupling portion coupled to the housing, the coupling portion comprising an uninterrupted, continuous cover portion that covers an entire area of a transverse projection of the width and length of the vent; and
a grip portion adjacent to the coupling portion, the grip portion having a width that is less than a width of the coupling portion.

19. The battery charger of claim 18, wherein the coupling portion is a first coupling portion, the handle further comprising:
a second coupling portion coupled to the housing;
wherein the grip portion is disposed between the first coupling portion and the second coupling portion.

20. The battery charger of claim 18, wherein an outermost portion of the handle is at least 45 mm from the housing.
